(19) United States
(12) Patent Application Publication
(10) Pub. No.: US 2009/0242121 A1
(43) Pub. Date: Oct. 1, 2009

(54) LOW STRESS, LOW-TEMPERATURE METAL-METAL COMPOSITE FLIP CHIP INTERCONNECT

(76) Inventor: Daewoong Suh, Phoenix, AZ (US)

Correspondence Address: INTEL CORPORATION;c/o CPA Global, P.O. BOX 52050, MINNEAPOLIS, MN, 55402, US

(21) Appl. No.: 12/058,949

(22) Filed: Mar. 31, 2008

(51) Int. Cl. B32B 37/12; B32B 15/04; B05D 1/36

(52) U.S. Cl. 156/325; 427/201; 428/457

(57) ABSTRACT

In some embodiments, a low stress, low-temperature metal-metal composite flip chip interconnect is presented. In this regard, a method is introduced consisting of combining a powder of substantially pure tin with a powder of tin alloy having a lower melting point than pure tin and depositing the combination of metals between an integrated circuit device and a package substrate. Other embodiments are also disclosed and claimed.

### BACK GROUND OF THE INVENTION

Interconnects between substrates and flip-chip integrated circuit devices are subject to thermal and mechanical stresses during manufacturing. It is important that interconnects have adequate plasticity or softness to prevent cracking and other issues. Though soft, lead can not be used and indium is too expensive. Tin is a soft metal that can be used, however its melting point is prohibitively high (about 250 degrees Celsius).

### BRIEF DESCRIPTION OF THE DRAWINGS

While the specification concludes with claims particularly pointing out and distinctly claiming that which is regarded as the present invention, the advantages of this invention can be more readily ascertained from the following description of the invention when read in conjunction with the accompanying drawings in which:

FIG. 1 represents a metal-metal composite according to an embodiment of the present invention.

FIG. 2 represents the metal-metal composite of FIG. 1 after liquid phase sintering according to an embodiment of the present invention.

FIG. 3 represents a low stress, low-temperature metal-metal composite flip chip interconnect according to an embodiment of the present invention.

### DETAILED DESCRIPTION OF THE PRESENT INVENTION

In the following detailed description, reference is made to the accompanying drawings that show, by way of illustration, specific embodiments in which the invention may be practiced. These embodiments are described in sufficient detail to enable those skilled in the art to practice the invention. It is to be understood that the various embodiments of the invention, although different, are not necessarily mutually exclusive. For example, a particular feature, structure, or characteristic described herein, in connection with one embodiment, may be implemented within other embodiments without departing from the spirit and scope of the invention. In addition, it is to be understood that the location or arrangement of individual elements within each disclosed embodiment may be modified without departing from the spirit and scope of the invention. The following detailed description is, therefore, not to be taken in a limiting sense, and the scope of the present invention is defined only by the appended claims, appropriately interpreted, along with the full range of equivalents to which the claims are entitled. In the drawings, like numerals refer to the same or similar functionality throughout the several views.

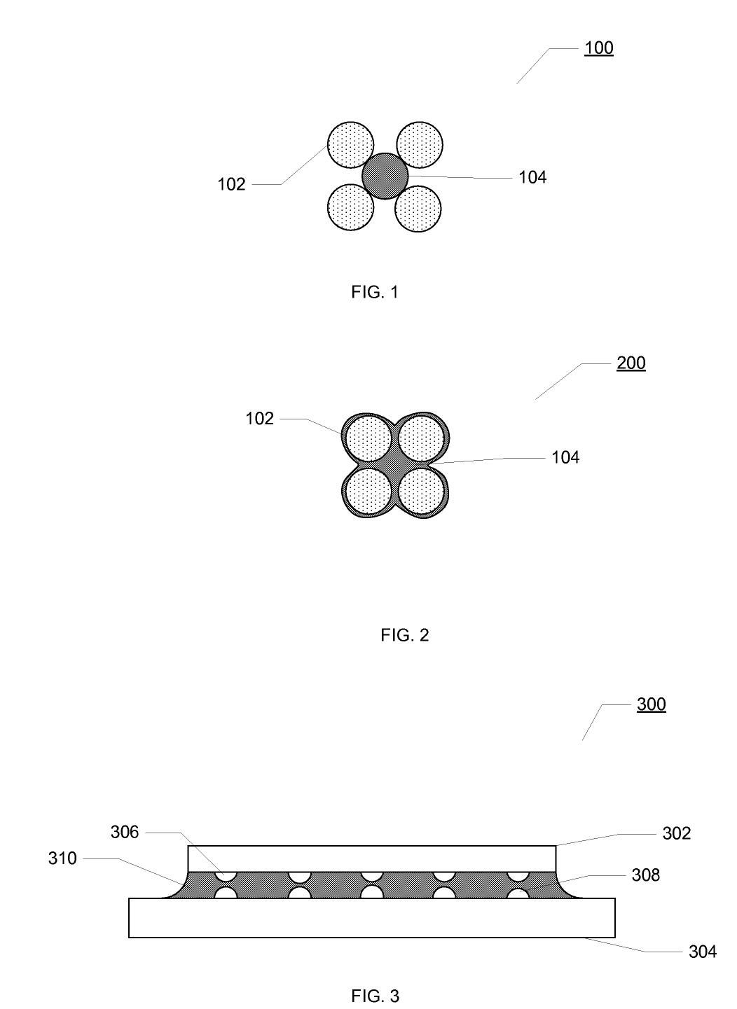

FIG. 1 represents a metal-metal composite according to an embodiment of the present invention. As shown, composite 100 contains first metal 102 and second metal 104. In one embodiment, first metal 102 and second metal 104 are combined in powder form to form a paste.

First metal 102 represents pure tin or an alloy of substantially pure tin that retains the plasticity properties of tin.

Second metal 104 represents a metal alloy with a lower melting temperature than first metal 102. In one embodiment, second metal 104 is a tin alloy that includes copper, silver, bismuth, zinc, indium, titanium and yttrium, or combinations thereof. The alloying elements in second metal 104 act as melting point depressants (MPD) and the percentage of alloying elements present can be predetermined to achieve a desired melting temperature. For example, second metal 104 can be designed based on the following empirical relationship:

Liquidus Temp(K)=499.79−1.799(Mol % of alloying elements)

In other words, the melting temperature of second metal 104 does not depend on specific alloying elements, but rather on the total amount of alloying elements. Based on this relationship, a variety of second metal 104 tin alloys can be designed in order to meet any specific reflow temperature target. For example, for a target melting temperature of 210 C., the mol % of alloying elements would be 9.33% ((499.79−483)/1.799) leading to the following example tin alloys.

TABLE 1
Alloying element (mol %)

| | | | | | | | | | Total |
|---|---|---|---|---|---|---|---|---|---|
| | | | | | | | | Total | target % for |
| Alloy | Cu | Ag | Bi | Zn | In | Ti | Y | % | 210 C. |
| Eutectic % | 1.3 | 3.8 | 43 | 14.9 | 51.7 | 0.5 | 1.6 | | 9.33 |
| Alloy 1 | 1.3 | 3.8 | 2 | 2 | 0.23 | | | 9.33 | |
| Alloy 2 | 1.3 | 3.8 | 4 | | 0.23 | | | 9.33 | |
| Alloy 4 | 1.3 | 3.8 | | 4 | 0.23 | | | 9.33 | |
| Alloy 5 | 1.3 | 3.8 | 2 | 0.23 | 2 | | | 9.33 | |
| Alloy 6 | 1.3 | 3.8 | 1 | 0.23 | 3 | | | 9.33 | |
| Alloy 7 | 1.3 | 3.8 | 3 | 0.23 | 1 | | | 9.33 | |
| Alloy 8 | 1.3 | 3.8 | 0.23 | 2 | 2 | | | 9.33 | |
| Alloy 9 | 1.3 | 3.8 | 0.23 | 1 | 3 | | | 9.33 | |
| Alloy 10 | 1.3 | 3.8 | 0.23 | 3 | 1 | | | 9.33 | |
| Alloy 11 | 1.3 | 3.8 | 1.86 | | 1.87 | 0.5 | | 9.33 | |
| Alloy 12 | 1.3 | 3.8 | 0.6 | | 3.13 | 0.5 | | 9.33 | |
| Alloy 13 | 1.3 | 3.8 | 3.23 | 0.5 | | 0.5 | | 9.33 | |
| Alloy 14 | 1.3 | 3.8 | | 0.5 | 3.23 | 0.5 | | 9.33 | |

In another example, for a target melting temperature of 120 C., the mol % of alloying elements would be 59.36% ((499.79−393)/1.799) leading to the following example tin alloys.

TABLE 2
Alloying element (mol %)

| | | | | | | | | Total | Target |
|---|---|---|---|---|---|---|---|---|---|
| | | | | | | | | mol | total mol |
| Alloy | Cu | Ag | Bi | Zn | In | Ti | Y | % | % |
| Eutectic % | 1.3 | 3.8 | 43 | 14.9 | 51.7 | 0.5 | 1.6 | | 59.36 |
| Alloy 1 | 1.3 | 3.8 | 30 | 5 | 20 | | | 60.10 | |
| Alloy 2 | 1.3 | 3.8 | 30 | 14.9 | 10 | | | 60.00 | |
| Alloy 4 | 1.3 | 3.8 | 30 | 0 | 25 | | | 60.10 | |
| Alloy 4 | 1.3 | 3.8 | 43 | 12 | 0 | | | 60.10 | |
| Alloy 5 | 1.3 | 3.8 | 43 | 0 | 12 | | | 60.10 | |
| Alloy 6 | 1.3 | 3.8 | 0 | 14.9 | 40 | | | 60.00 | |
| Alloy 7 | 1.3 | 3.8 | 0 | 3.2 | 51.7 | | | 60.00 | |

FIG. 2 represents the metal-metal composite of FIG. 1 after liquid phase sintering according to an embodiment of the present invention. As shown, composite 200 has been heating causing second metal 104 to melt, but not so hot as to melt first metal 102. As a result of transient liquid phase sintering (TLPS) each inter-particle space becomes a capillary where a substantial capillary pressure is developed. At the same time, interdiffusion between constituent elements happens at the joint between first metal 102 particles. Through continued heating, for example during reflow, the interface area becomes homogenized and eventually will have a higher remelting temperature. Through experimentation, the relative amount of second metal 104 may be chosen to optimize transient liquid phase bonding time and maximize the remelting temperature for suitable reliability while minimizing strengthening effects on first metal 102 for maintaining low stress plasticity.

FIG. 3 represents a low stress, low-temperature metal-metal composite flip chip interconnect according to an embodiment of the present invention. Shown is package structure 300, wherein a die 302 is flip-chip connected with a substrate 304. Die bumps 306, substrate bumps 308 and/or soldering material 310 may incorporate a metal-metal composite as described above. One skilled in the art would appreciate that in this way standard processes may be used to produce a low stress, low-temperature flip chip interconnect.

In one embodiment, composite 100 may be used as a soldering material 310 on substrate 304. Die 302 may then be placed onto substrate 304 and the whole assembly is reflowed at the same time at a temperature above the melting temperature of second metal 104. The solder paste will form an interconnect between substrate bumps 308 and die bumps 306 through self-assembly. During self-assembly, first metal 102 will be embedded into second metal 104 leading to a metal-metal microstructure.

In another embodiment, composite 100 paste can be used for forming substrate bumps 308 using a standard process. Die 302 can then be attached using a standard process. In this case, composite 100 should be formulated so that interdiffusion is slow enough to survive a second reflow during the chip attach process. In other embodiments, composite 100 may be incorporated to varying degrees into substrate bumps 308 (or die bumps 306) as well as into soldering material 310.

Although the foregoing description has specified certain steps and materials that may be used in the method of the present invention, those skilled in the art will appreciate that many modifications and substitutions may be made. Accordingly, it is intended that all such modifications, alterations, substitutions and additions be considered to fall within the spirit and scope of the invention as defined by the appended claims. In addition, it is appreciated that certain aspects of microelectronic devices are well known in the art. Therefore, it is appreciated that the Figures provided herein illustrate only portions of an exemplary microelectronic structure that pertains to the practice of the present invention. Thus the present invention is not limited to the structures described herein.

What is claimed is:

1. A method comprising:
combining a powder of substantially pure tin with a powder of tin alloy having a lower melting point than pure tin; and
depositing the combination of metals between an integrated circuit device and a package substrate.

2. The method of claim 1 wherein the tin alloy comprises at least one metal chosen from the group consisting of: copper, silver, bismuth, zinc, indium, titanium and yttrium.

3. The method of claim 1 further comprising heating the combination of metals until the tin alloy melts.

4. The method of claim 3 further comprising continuing to heat the combination of metals until homogenization is reached.

5. The method of claim 1 wherein the tin alloy comprises a percentage of alloying elements to achieve a melting temperature of about 210 degrees Celsius.

6. The method of claim 1 wherein the tin alloy comprises a percentage of alloying elements to achieve a melting temperature of about 120 degrees Celsius.

7. The method of claim 1 wherein a relative amount of tin alloy is chosen to optimize transient liquid phase bonding time while maintaining plasticity.

8. A method comprising:
combining a powder of substantially pure tin with a powder of tin alloy having a lower melting point than pure tin; and
forming the combination of metals into bumps on an integrated circuit package substrate.

9. The structure of claim 8 wherein the tin alloy comprises at least one metal chosen from the group consisting of: copper, silver, bismuth, zinc, indium, titanium and yttrium.

10. The structure of claim 8 further comprising coupling an integrated circuit device to the bumps on the substrate and reflowing the bumps.

11. The method of claim 10 further comprising continuing to reflow the bumps until homogenization is reached.

12. The method of claim 8 wherein the tin alloy comprises a percentage of alloying elements to achieve a melting temperature of about 210 degrees Celsius.

13. The method of claim 8 wherein the tin alloy comprises a percentage of alloying elements to achieve a melting temperature of about 120 degrees Celsius.

14. The method of claim 8 wherein a relative amount of tin alloy is chosen to optimize transient liquid phase bonding time while maintaining plasticity.

15. A method comprising:
combining a powder of substantially pure tin with a powder of tin alloy having a lower melting point than pure tin to form a paste;
dispensing the paste onto a substrate;
placing an integrated circuit chip on the paste; and
reflowing the paste.

16. The method of claim 15 wherein the tin alloy comprises at least one metal chosen from the group consisting of: copper, silver, bismuth, zinc, indium, titanium and yttrium.

17. The method of claim 15 wherein the tin alloy comprises a percentage of alloying elements to achieve a melting temperature of about 210 degrees Celsius.

18. The method of claim 15 wherein the tin alloy comprises a percentage of alloying elements to achieve a melting temperature of about 120 degrees Celsius.

19. The method of claim 15 wherein a relative amount of tin alloy is chosen to optimize transient liquid phase bonding time while maintaining plasticity.
